(19) United States
(12) Patent Application Publication
(10) Pub. No.: US 2025/0333841 A1
(43) Pub. Date: Oct. 30, 2025

(54) FILM FORMING APPARATUS AND CLEANING METHOD

(71) Applicant: Tokyo Electron Limited, Tokyo (JP)

(72) Inventors: Masami OIKAWA, Oshu City (JP); Tsubasa WATANABE, Oshu City (JP)

(21) Appl. No.: 19/188,123

(22) Filed: Apr. 24, 2025

(30) Foreign Application Priority Data
Apr. 26, 2024 (JP) 2024-072021

(51) Int. Cl. C23C 16/44; C23C 16/40

(52) U.S. Cl. CPC C23C 16/4405; C23C 16/401; C23C 16/4412

(57) ABSTRACT

A film forming apparatus that forms a film containing silicon and oxygen, includes: a processing container in which the film is formed in an interior of the processing container; a supply flow path configured to supply a cleaning gas to the interior of the processing container; an exhaust flow path configured to exhaust the interior of the processing container; and a moisture introducer configured to introduce moisture into the exhaust flow path.

### CROSS-REFERENCE TO RELATED APPLICATION

This application is based upon and claims the benefit of priority from Japanese Patent Application No. 2024-072021, filed on Apr. 26, 2024, the entire contents of which are incorporated herein by reference.

### TECHNICAL FIELD

The present disclosure relates to a film forming apparatus and a cleaning method.

### BACKGROUND

A technique is known, in which a cleaning gas is introduced into an exhaust pipe connected to a reaction chamber to clean an interior of the exhaust pipe (see, for example, Patent Document 1).

### PRIOR ART DOCUMENTS

### Patent Documents

Patent Document 1: Japanese Laid-Open Patent Publication No. 2001-107234

### SUMMARY

According to one embodiment of the present disclosure, there is provided a film forming apparatus that forms a film containing silicon and oxygen, including: a processing container in which the film is formed in an interior of the processing container; a supply flow path configured to supply a cleaning gas to the interior of the processing container; an exhaust flow path configured to exhaust the interior of the processing container; and a moisture introducer configured to introduce moisture into the exhaust flow path.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram illustrating a film forming apparatus according to an embodiment.

FIG. 2 is a diagram illustrating an example of a film formation process.

FIG. 3 is a diagram illustrating an example of a container cleaning process.

FIG. 4 is a flowchart illustrating an example of a pump cleaning process.

FIG. 5 is a diagram illustrating the example of the pump cleaning process.

FIG. 6 is a diagram illustrating the example of the pump cleaning process.

FIG. 7 is a diagram illustrating another example of the pump cleaning process.

FIG. 8 is a diagram illustrating an example of a relationship between moisture concentration and etching amount.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

Hereinafter, non-limiting exemplary embodiments of the present disclosure will be described with reference to the accompanying drawings. In all the accompanying drawings, the same or corresponding members or components will be denoted by the same or corresponding reference numerals, and redundant descriptions thereof will be omitted.

### [Film Forming Apparatus]

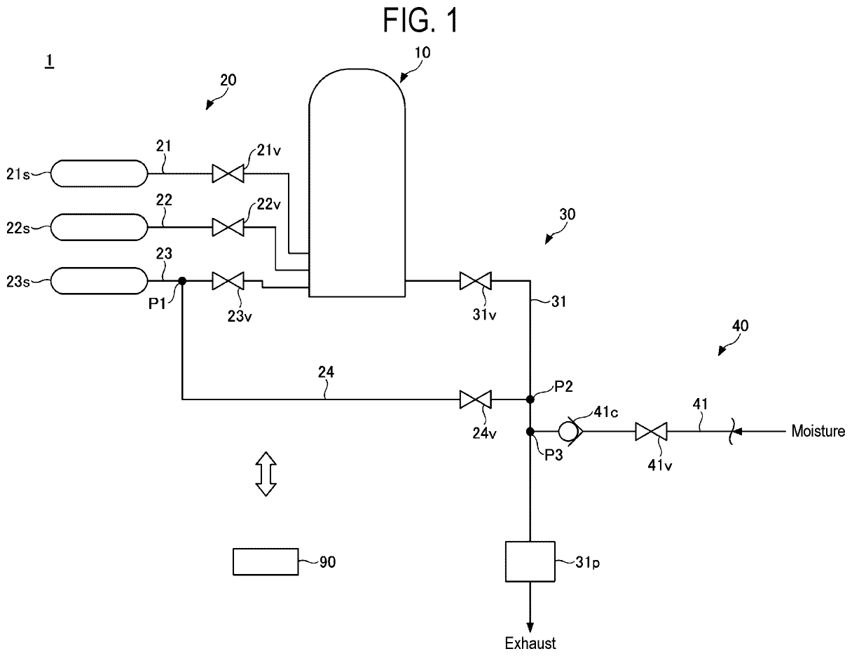

A film forming apparatus 1 according to an embodiment will be described with reference to FIG. 1. FIG. 1 is a diagram illustrating the film forming apparatus 1 according to the embodiment.

The film forming apparatus 1 includes a processing container 10, a gas supplier 20, an exhauster 30, a moisture introducer 40, and a controller 90.

The processing container 10 is a container in which a processing space capable of accommodating one or more substrates formed in the interior. In the processing space, a film containing silicon and oxygen is formed on the substrate. The substrate is, for example, a semiconductor wafer. The film containing silicon and oxygen is, for example, a silicon oxide film.

The gas supplier 20 has a first supply flow path 21, a second supply flow path 22, a third supply flow path 23, and a bypass flow path 24.

The first supply flow path 21 is connected to the processing container 10. The first supply flow path 21 is provided with a supply source 21s of silicon-containing gas and then an on-off valve 21v from the upstream side to the downstream side in the gas flow direction. The on-off valve 21v is a valve that switches the flow of the silicon-containing gas between on and off. When the on-off valve 21v is in the open state, it allows the silicon-containing gas to flow downstream, and when in the closed state, it stops the flow of the silicon-containing gas downstream. The first supply flow path 21 supplies the silicon-containing gas from the supply source 21s to the interior of the processing container 10. The supply timing of the silicon-containing gas from the supply source 21s is controlled by the on-off valve 21v. The first supply flow path 21 may also be provided with a mass flow controller.

The second supply flow path 22 is connected to the processing container 10. The second supply flow path 22 is provided with a supply source 22s of oxidizing gas and then an on-off valve 22v from the upstream side to the downstream side in the gas flow direction. The on-off valve 22v is a valve that switches the flow of the oxidizing gas between on and off. When the on-off valve 22v is in the open state, it allows the oxidizing gas to flow downstream, and when in the closed state, it stops the flow of the oxidizing gas downstream. The second supply flow path 22 supplies the oxidizing gas from the supply source 22s to the interior of the processing container 10. The supply timing of the oxidizing gas from the supply source 22s is controlled by the on-off valve 22v. The second supply flow path 22 may also be provided with a mass flow controller.

The third supply flow path 23 is connected to the processing container 10. The third supply flow path 23 is provided with a supply source 23s of hydrogen fluoride (H F) gas and then an on-off valve 23v from the upstream side to the downstream side in the gas flow direction. The on-off valve 23v is a valve that switches the flow of the hydrogen fluoride gas between on and off. When the on-off valve 23v is in the open state, it allows the hydrogen fluoride gas to flow downstream, and when in the closed state, it stops the flow of the hydrogen fluoride gas downstream. The third supply flow path 23 supplies the hydrogen fluoride gas from the supply source 23s to the interior of the processing container 10. The supply timing of the hydrogen fluoride gas from the supply source 23s is controlled by the on-off valve 23v. The third supply flow path 23 may also be provided with a mass flow controller. The hydrogen fluoride gas is an example of a cleaning gas.

The bypass flow path 24 branches off from an intermediate point of the third supply flow path 23 and merges into an intermediate point of an exhaust flow path 31. The bypass flow path 24 branches off from the third supply flow path 23 at a position P1 between the supply source 23s and the on-off valve 23v, and merges into the exhaust flow path 31 at a position P2 between an on-off valve 31v and an exhaust device 31p. The bypass flow path 24 is provided with an on-off valve 24v. The on-off valve 24v is a valve that switches the flow of the hydrogen fluoride gas between on and off. When the on-off valve 24v is in the open state, it allows the hydrogen fluoride gas to flow downstream, and when in the closed state, it stops the flow of the hydrogen fluoride gas downstream. The bypass flow path 24 supplies the hydrogen fluoride gas from the supply source 23s to the exhaust flow path 31 without passing through the interior of the processing container 10. The supply timing of the hydrogen fluoride gas from the supply source 23s is controlled by the on-off valve 24v. The bypass flow path 24 may also be provided with a mass flow controller.

The exhauster 30 has the exhaust flow path 31. The exhaust flow path 31 is connected to the processing container 10. The exhaust flow path 31 is provided with the on-off valve 31v and then the exhaust device 31p from the upstream side toward the downstream side in the gas flow direction. The on-off valve 31v is a valve that switches the flow of gas in the exhaust flow path 31 between on and off. When the on-off valve 31v is in the open state, it allows gas to flow downstream, and when in the closed state, it stops the flow of gas downstream. The exhaust device 31p includes a vacuum pump. The vacuum pump is, for example, a combination of a dry pump and a mechanical booster pump. The exhaust flow path 31 exhausts the internal gas of the processing container 10 using the exhaust device 31p. The exhaust timing of the internal gas from the processing container 10 is controlled by the on-off valve 31v.

The moisture introducer 40 has a moisture introduction flow path 41. The moisture introduction flow path 41 is connected to the exhaust flow path 31 at a position P3 farther from the processing container 10 than the position P2 in which the bypass flow path 24 merges into the exhaust flow path 31. The moisture introduction flow path 41 may also be connected to the exhaust flow path 31 at a position closer to the processing container 10 than the position P2 in which the bypass flow path 24 merges into the exhaust flow path 31. Moisture is introduced into the moisture introduction flow path 41. The moisture is, for example, water vapor generated by a water vapor generator. The moisture may also be atmospheric air. The moisture introduction flow path 41 is provided with an on-off valve 41v and then a check valve 41c from the upstream side to the downstream side in the moisture flow direction. The on-off valve 41v is a valve that switches the flow of moisture through the moisture introduction flow path 41 between on and off. When the on-off valve 41v is in the open state, it allows the moisture to flow downstream, and when in the closed state, it stops the flow of the moisture downstream. The check valve 41c prevents the reverse flow of gas from the exhaust flow path 31 to the moisture introduction flow path 41. The moisture introduction flow path 41 introduces the moisture into the exhaust flow path 31. The supply timing of the moisture is controlled by the on-off valve 41v. The moisture introduction flow path 41 may also be provided with an orifice.

The controller 90 is an electronic circuit such as a Central Processing U nit (CPU), Field Programmable Gate Array (FPGA), or Application Specific Integrated Circuit(ASIC). The controller 90 executes various control operations described herein by executing instruction codes stored in a computer readable memory or by being designed as a circuit for specific purposes.

### [Operation of the Film Forming Apparatus]

The operation of the film forming apparatus 1 according to the embodiment will be described. The operation of the film forming apparatus 1 described below is automatically executed under the control of the controller 90.

### (Film Formation Process)

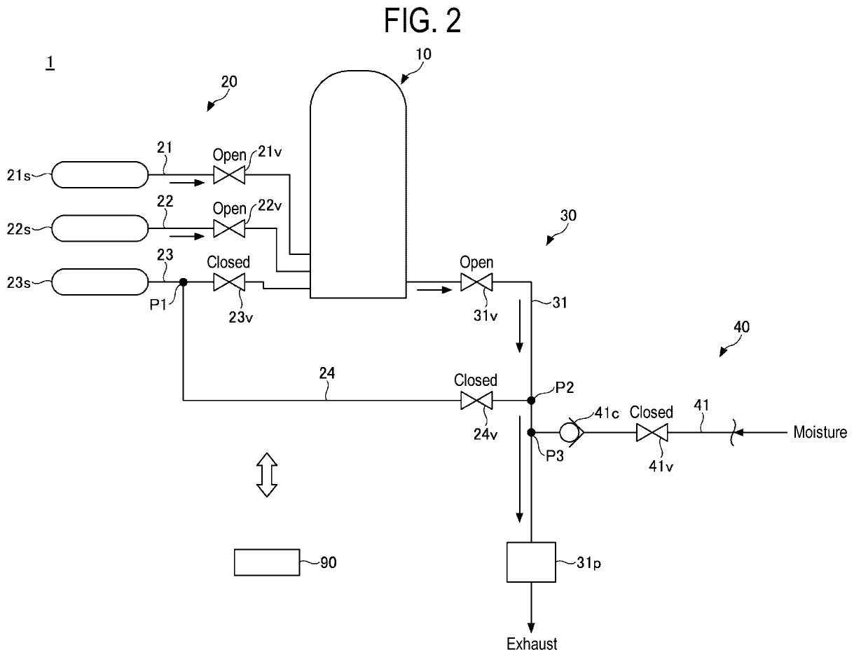

The operation of the film forming apparatus 1 when performing a film formation process will be described with reference to FIG. 2. FIG. 2 is a diagram illustrating an example of a film formation process. In FIG. 2, the arrows indicate the flow of gas.

As illustrated in FIG. 2, in the film formation process, the controller 90 controls the on-off valves 21v, 22v and 31v to the open state and the on-off valves 23v, 24v and 41v to the closed state. This allows the silicon-containing gas from the supply source 21s to be supplied to the interior of the processing container 10 via the first supply flow path 21, and the oxidizing gas from the supply source 22s to be supplied to the interior of the processing container 10 via the second supply flow path 22. When the silicon-containing gas and oxidizing gas are supplied to the interior of the processing container 10, a silicon oxide film is formed on the substrate.

In the film formation process, the silicon oxide film is deposited not only on the surface of the substrate but also in the interior of the processing container 10 such as on the inner wall of the processing container 10 and internal components of the processing container 10. The silicon-containing gas and oxidizing gas, which were not consumed in the interior of the processing container 10, are exhausted via the exhaust flow path 31 by the exhaust device 31p. Since the silicon-containing gas and oxidizing gas, which are exhausted through the exhaust flow path 31, enter the exhaust device 31p, a silicon oxide film is also deposited in the interior of the exhaust device 31p. As film formation is performed repeatedly on the substrate, the amount of silicon oxide film deposited in the interior of the processing container 10 or in the interior of the exhaust device 31p increases. Therefore, after a predetermined number of film formation cycles, the controller 90 executes container cleaning to remove the silicon oxide film deposited in the interior of the processing container 10 and pump cleaning to remove the silicon oxide film deposited in the interior of the exhaust device 31p.

### (Container Cleaning Process)

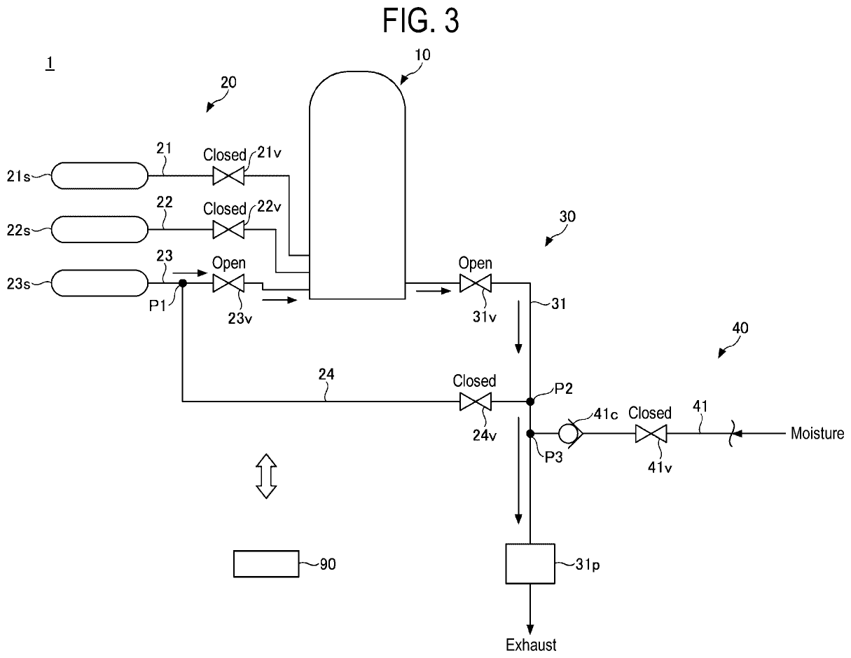

The operation of the film forming apparatus 1 when performing a container cleaning process will be described with reference to FIG. 3. FIG. 3 is a diagram illustrating an example of a container cleaning process. In FIG. 3, the arrows indicate the flow of gas.

As illustrated in FIG. 3, in the container cleaning process, the controller 90 controls the on-off valves 23v and 31v to the open state, and the on-off valves 21v, 22v, 24v and 41v to the closed state. This allows the hydrogen fluoride gas from the supply source 23s to be supplied to the interior of the processing container 10 via the third supply flow path 23. When the hydrogen fluoride gas is supplied to the interior of the processing container 10, the hydrogen fluoride gas reacts with the silicon oxide film deposited in the interior of the processing container 10, removing the silicon oxide film.

### (Pump Cleaning Process)

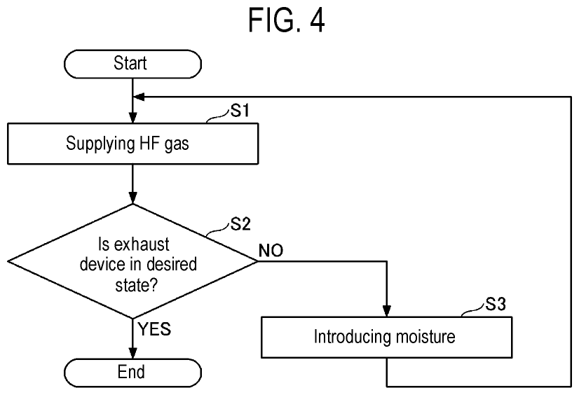

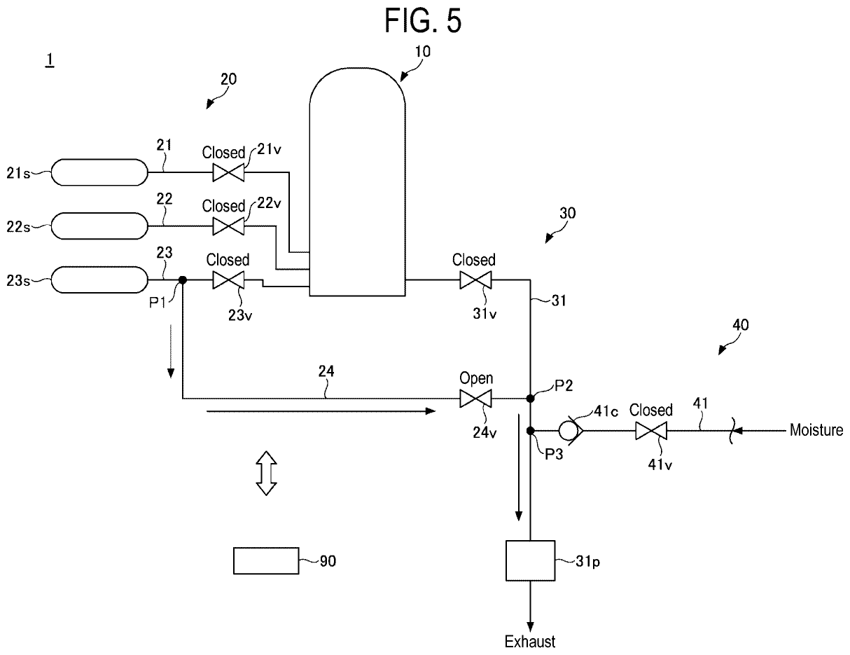

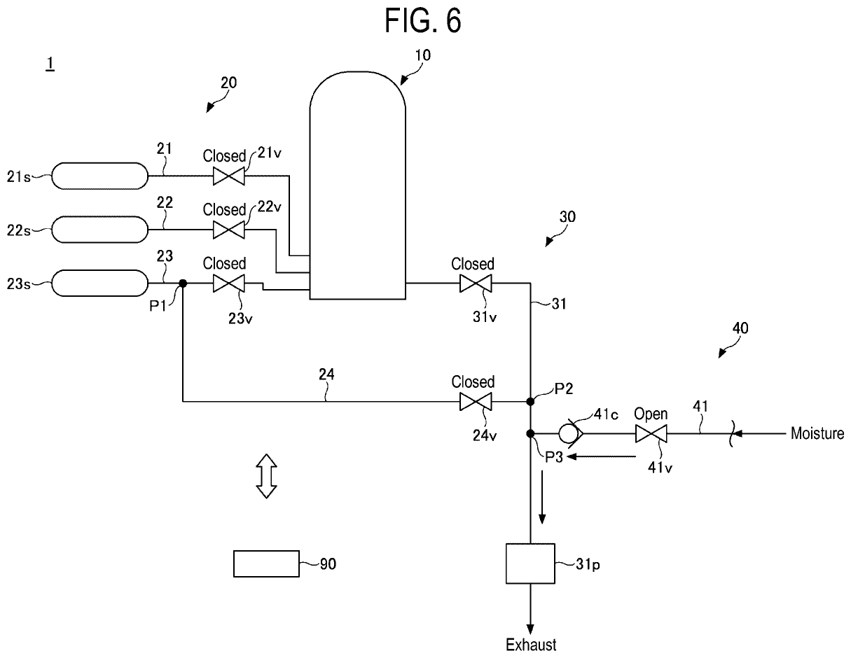

The operation of the film forming apparatus 1 when performing a pump cleaning process will be described with reference to FIGS. 4 to 6. FIG. 4 is a flowchart illustrating an example of a pump cleaning process. FIGS. 5 and 6 are diagrams illustrating the example of the pump cleaning process. In FIGS. 5 and 6, the arrows indicate the flow of gas. In the pump cleaning process, steps S1 to S3 as illustrated in FIG. 4 are performed.

In step S1, the controller 90 controls the on-off valve 24v to the open state, and the on-off valves 21v, 22v, 23v, 31v and 41v to the closed state (see FIG. 5). This allows the hydrogen fluoride gas from the supply source 23s to enter the exhaust flow path 31 via the bypass flow path 24 and reach the exhaust device 31p without passing through the interior of the processing container 10. In this case, the hydrogen fluoride gas before being consumed in the reaction with the silicon oxide film may be supplied to the exhaust device 31p. Therefore, the hydrogen fluoride gas reacts with the silicon oxide film deposited in the interior of the exhaust device 31p, and the silicon oxide film is removed. At this time, since no hydrogen fluoride gas is supplied to the interior of the processing container 10, it is possible to prevent the interior of the processing container 10 from being over-etched by the hydrogen fluoride gas.

In step S2, the controller 90 determines whether the exhaust device 31p is in a desired state. The desired state is, for example, a state in which the thickness of the silicon oxide film in the interior of the exhaust device 31p is equal to or less than a desired thickness. For example, if the back pressure of the vacuum pump included in the exhaust device 31p is equal to or less than a threshold, the controller 90 determines that the thickness of the silicon oxide film in the interior of the exhaust device 31p is equal to or less than the desired thickness. In contrast, if the back pressure of the vacuum pump included in the exhaust device 31p exceeds the threshold, the controller 90 determines that the thickness of the silicon oxide film in the interior of the exhaust device 31p is above the desired thickness. For example, if the load of the vacuum pump included in the exhaust device 31p is equal to or less than a threshold, the controller 90 determines that the thickness of the silicon oxide film in the interior of the exhaust device 31p is equal to or less than the desired thickness. In contrast, if the load of the vacuum pump included in the exhaust device 31p exceeds the threshold, the controller 90 determines that the thickness of the silicon oxide film in the interior of the exhaust device 31p is above the desired thickness.

In step S2, if the exhaust device 31p is in the desired state (“YES” in step S2), the process ends. In step S2, if the exhaust device 31p is not in the desired state (“NO” in step S2), the process proceeds to step S3.

In step S3, the controller 90 switches the on-off valve 24v from the open state to the closed state and the on-off valve 41v from the closed state to the open state (Se FIG. 6). This stops the supply of the hydrogen fluoride gas from the supply source 23s to the exhaust flow path 31, while allowing the moisture to be introduced from the moisture introduction flow path 41 into the exhaust flow path 31. The moisture introduced into the exhaust flow path 31 increases the moisture content in the silicon oxide film deposited in the interior of the exhaust device 31p. After step S3, step S1 is performed again. When step S1 follows step S3, the hydrogen fluoride gas supplied to the exhaust device 31p reacts with the silicon oxide film deposited in the interior of the exhaust device 31p, removing the silicon oxide film. The higher the moisture content in the silicon oxide film, the more easily the silicon oxide film reacts with the hydrogen fluoride gas. Therefore, in step S1 following step S3, it is easy to remove the silicon oxide film.

As described above, the controller 90 performs two tasks: introducing the moisture from the moisture introducer 40 into the exhaust flow path 31 (step S3) and supplying the hydrogen fluoride gas from the third supply flow path 23 to the exhaust flow path 31 (step S1). In this case, the moisture content in the silicon oxide film deposited in the interior of the exhaust device 31p increases, which facilitates the reaction between the silicon oxide film and the hydrogen fluoride gas. Therefore, reaction products such as the silicon oxide film deposited in the interior of the exhaust device 31p may be efficiently removed.

The controller 90 non-simultaneously performs introducing the moisture from the moisture introducer 40 into the exhaust flow path 31 (step S3) and supplying the hydrogen fluoride gas from the third supply flow path 23 to the exhaust flow path 31 (step S1). In this case, the moisture may be introduced into the exhaust device 31p without reacting with the hydrogen fluoride gas. Therefore, it is easy to increase the moisture content in the silicon oxide film in the interior of the exhaust device 31p.

The controller 90 repeats introducing the moisture from the moisture introducer 40 into the exhaust flow path 31 (step S3) and then supplying the hydrogen fluoride gas from the third supply flow path 23 to the exhaust flow path 31 (step S1) until the exhaust device 31p reaches the desired state. In this case, the thickness of the silicon oxide film deposited in the interior of the exhaust device 31p may be reduced to be equal to or less than the desired thickness.

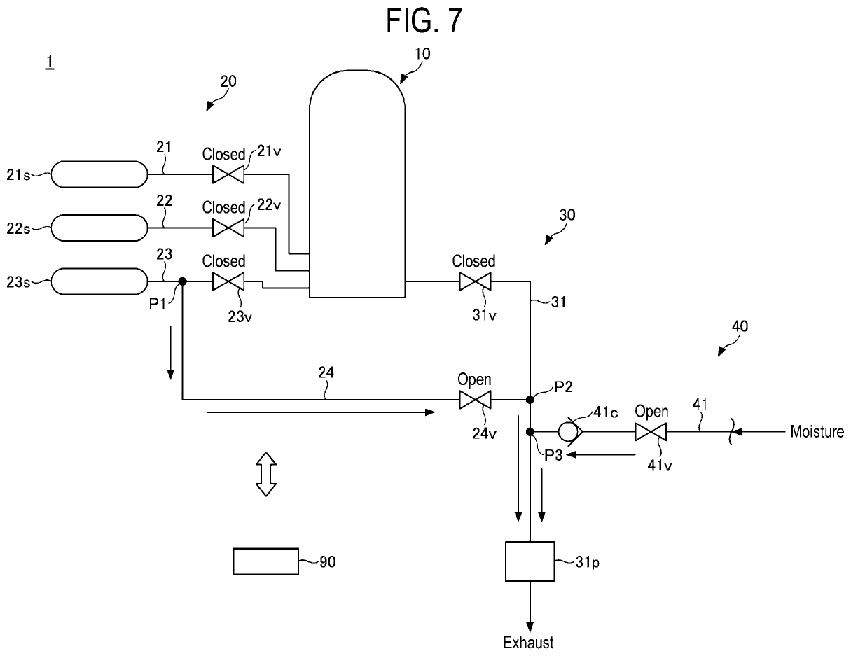

FIG. 7 is a diagram illustrating another example of the pump cleaning process. As illustrated in FIG. 7, in the pump cleaning process, the controller 90 may simultaneously perform introducing the moisture from the moisture introducer 40 into the exhaust flow path 31 (step S3) and supplying the hydrogen fluoride gas from the third supply flow path 23 to the exhaust flow path 31 (step S1). Specifically, the controller 90 controls the on-off valves 24v and 41v to the open state, and the on-off valves 21v, 22v, 23v and 31v to the closed state. This allows the hydrogen fluoride gas from the supply source 23s to enter the exhaust flow path 31 via the bypass flow path 24 and reach the exhaust device 31p without passing through the interior of the processing container 10. At the same time, this allows the moisture to be introduced from the moisture introduction flow path 41 into the exhaust flow path 31 and reach the exhaust device 31p. In this case, it is desirable that the moisture introduction flow path 41 is connected to the exhaust flow path 31 immediately before the exhaust device 31p. This allows for the simultaneous supply of both hydrogen fluoride gas and the moisture into the exhaust flow path 31 without causing a reaction between the moisture and the hydrogen fluoride gas, and it is possible to easily introduce the moisture into the exhaust device 31p.

### Evaluation Results

The effect of the moisture content in the silicon oxide film on the etching amount of the silicon oxide film was evaluated. First, a substrate formed with Film A and a substrate formed with Film B were accommodated in the interior of the processing container 10 of the film forming apparatus 1. The hydrogen fluoride gas was supplied from the supply source 23s to the interior of the processing container 10 via the third supply flow path 23, and both Film A and Film B were etched. The etching amounts of Film A and Film B were then measured. Film A is a silicon oxide film with a moisture (H₂O) concentration of 1.0×10²¹ atoms/cm³. Film B is a silicon oxide film with a moisture concentration of 4.9×10²⁰ atoms/cm³.

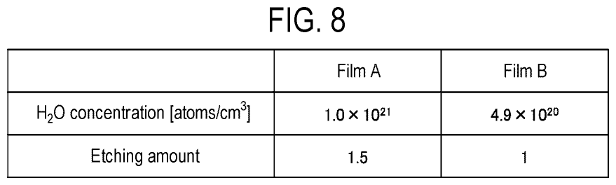

FIG. 8 is a diagram illustrating an example of a relationship between moisture concentration and etching amount. In FIG. 8, the etching amount of Film A is presented as a relative value with the etching amount of Film B set to 1. As illustrated in FIG. 8, it can be seen that the etching amount of Film A is greater than that of Film B. From this result, it can be said that a higher moisture content in the silicon oxide film makes the silicon oxide film more susceptible to etching by the hydrogen fluoride gas.

The embodiments disclosed herein should be considered as illustrative and not restrictive in all respects. The above embodiments may be omitted, replaced, or changed in various forms without departing from the scope of the appended claims and their spirit.

According to the present disclosure, it is possible to remove reaction products deposited in the interior of an exhaust device.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A film forming apparatus that forms a film containing silicon and oxygen, comprising:
a processing container in which the film is formed in an interior of the processing container;
a supply flow path configured to supply a cleaning gas to the interior of the processing container;
an exhaust flow path configured to exhaust the interior of the processing container; and
a moisture introducer configured to introduce moisture into the exhaust flow path.

2. The film forming apparatus of claim 1, further comprising: a bypass flow path that branches off from an intermediate point of the supply flow path and merges into an intermediate point of the exhaust flow path.

3. The film forming apparatus of claim 2, wherein the moisture introducer includes a moisture introduction flow path configured to introduce the moisture into the exhaust flow path, and
wherein the moisture introduction flow path is connected to the exhaust flow path at a position farther from the processing container than a position in which the bypass flow path merges into the exhaust flow path.

4. The film forming apparatus of claim 3, wherein the moisture introducer has a check valve installed in the moisture introduction flow path.

5. The film forming apparatus of claim 4, further comprising: a controller,
wherein the controller performs a process including:
introducing the moisture from the moisture introducer into the exhaust flow path; and
supplying the cleaning gas from the supply flow path into the exhaust flow path.

6. The film forming apparatus of claim 5, wherein the controller non-simultaneously performs the introducing the moisture and the supplying the cleaning gas.

7. The film forming apparatus of claim 6, wherein an exhaust device is installed in the exhaust flow path, and
wherein the controller repeats the introducing the moisture and then the supplying the cleaning gas until the exhaust device reaches a desired state.

8. The film forming apparatus of claim 5, wherein the controller simultaneously performs the introducing the moisture and the supplying the cleaning gas.

9. The film forming apparatus of claim 5, wherein in the supplying the cleaning gas, the cleaning gas is supplied to the exhaust flow path via the bypass flow path without passing through the interior of the processing container.

10. The film forming apparatus of claim 1, further comprising: a controller,
wherein the controller performs a process including:
introducing the moisture from the moisture introducer into the exhaust flow path; and
supplying the cleaning gas from the supply flow path into the exhaust flow path.

11. The film forming apparatus of claim 1, wherein the film is a silicon oxide film.

12. A cleaning method for a film forming apparatus that forms a film containing silicon and oxygen,
wherein the film forming apparatus comprises:
a processing container in which the film is formed in an interior of the processing container;
a supply flow path configured to supply a cleaning gas to the interior of the processing container;
an exhaust flow path configured to exhaust the interior of the processing container; and
a moisture introducer configured to introduce moisture into the exhaust flow path, and
wherein the cleaning method comprises:
introducing the moisture from the moisture introducer into the exhaust flow path; and
supplying the cleaning gas from the supply flow path into the exhaust flow path.
